(19) United States
(12) Patent Application Publication
(10) Pub. No.: US 2022/0242051 A1
(43) Pub. Date: Aug. 4, 2022

(54) SYSTEM AND METHOD FOR 3D PRINTING A SUPPORT STRUCTURE

(71) Applicant: STRATASYS LTD., Rehovot (IL)

(72) Inventor: Nur ARAD, Tel-Aviv (IL)

(73) Assignee: STRATASYS LTD., Rehovot (IL)

(21) Appl. No.: 17/617,592

(22) PCT Filed: Jun. 11, 2020
(86) PCT No.: PCT/IL2020/050649

§ 371 Date: Dec. 9, 2021

Related U.S. Application Data
(60) Provisional application No. 62/860,894, filed on Jun. 13, 2019.

(51) Int. Cl. B29C 64/40; B29C 64/386; B33Y 50/00; G05B 19/4099

(52) U.S. Cl. CPC B29C 64/40; B29C 64/386; G05B 2219/49023; G05B 19/4099; B33Y 50/00

(57) ABSTRACT

Systems and methods for predefining at least one support structure for at least one three-dimensional object for printing thereof using a three-dimensional printing system are disclosed. Default support structures are replaced by improved support structures or not depending on the result of an assessment, based on predefined rules of the body region in the slice that needs support.

### FIELD OF THE INVENTION

The present invention relates to the field of three-dimensional (3D) inkjet printing, and more particularly, to support structures for printing three-dimensional objects.

### BACKGROUND OF THE INVENTION

In three-dimensional (3D) inkjet printing of a 3D object, material is selectively jetted from one or more print heads and deposited onto a fabrication tray in consecutive layers according to a pre-determined configuration as defined by a software file. Some deposition processes include depositing different materials in order to form a single object or model. For example, an object may be built by depositing a first material for forming the body structure and a second material for forming a support structure to support various sections of the body structure, for example, negative angle surfaces and overhangs. The support structure is later removed by mechanical, chemical or other means to reveal the final object.

### SUMMARY OF THE INVENTION

Some embodiments of the present invention may provide a method of defining at least one support structure for at least one 3D object to be printed using a 3D printing system, the method comprising: receiving a 3D digital model of at least one 3D object to be printed; slicing the 3D digital model to generate multiple slices, wherein each of at least some of the multiple slices includes at least one body region that represents a respective horizontal cross-section of the at least one 3D object; identifying at least one slice of the multiple slices that includes at least one body region that has to be supported by at least one support structure when printing the at least one 3D object; determining whether the at least one body region in the at least one identified slice meets a predetermined set of rules; if the at least one body region in the at least one identified slice does not meet the predetermined set of rules, defining at least one default support structure for the at least one body region in the at least one identified slice; and if the at least one body region in the at least one identified slice meets the predetermined set of rules, defining at least one improved support structure for the at least one body region in the at least one identified slice.

In some embodiments, the at least one improved support structure is at least one of occupies less space on a fabrication tray of the 3D printing system and requires less supporting material than the at least one default support structure.

In some embodiments, defining the at least one improved support structure comprises: selecting a subset of preceding slices of the multiple slices that precede the at least one identified slice, wherein each of the slices of the subset of preceding slices has to include at least one support region to be filled with a supporting material when printing the at least one 3D object, to thereby form the at least one support structure needed to support the at least one body region in the at least one identified slice; and defining at least one support region for each slice of the subset of preceding slices such that a width of the at least one support region in the subset of preceding slices gradually increases between a last slice in the subset that is adjacent to the at least one identified slice and a first slice in the subset.

In some embodiments, determining that the at least one body region in the at least one identified slice meets the predetermined set of rules comprises: determining that a width of the at least one body region in the at least one identified slice is smaller than a specified width threshold.

In some embodiments, determining that the at least one body region in the at least one identified slice meets the predetermined set of rules comprises: determining that a distance between the at least one body region in the at least one identified slice and at least one body region in one of preceding slices immediately below the at least one body region in the at least one identified slice or the fabrication tray is larger than a specified distance threshold.

In some embodiments, determining that the at least one body region in the at least one identified slice meets the predetermined set of rules comprises: determining that a length of the at least one body region in the at least one identified slice is larger than a specified length threshold.

In some embodiments, determining that the at least one body region in the at least one identified slice meets the predetermined set of rules comprises: determining that there are no body regions in at least one slices that are subsequent to the at least one identified slice that is wider than the at least one body region in the at least one identified slice.

In some embodiments, the method comprising: determining if the at least one improved support structure defined for the at least one 3D object obstruct the construction of at least one other 3D object on the fabrication tray; and if so, modifying a location of one or more of the at least one 3D object and the at least one another 3D object on the fabrication tray to avoid the obstruction thereof.

Some embodiments of the present invention may provide a system for defining at least one support structure for at least one 3D object for printing thereof using a 3D printing system, the system comprising: a slicing module configured to: receive a 3D digital model of at least one 3D object to be printed using a 3D printing system; and slice the 3D digital model to generate multiple slices, wherein each of at least some of the multiple slices includes at least one body region that represents a respective horizontal cross-section of the at least one 3D object; and a support structure definition module configured to: identify at least one slice of the multiple slices that includes at least one body region that has to be supported by at least one support structure when printing the at least one 3D object; determine whether the at least one body region in the at least one identified slice meets a predetermined set of rules; if the at least one body region in the at least one identified slice does not meet a predetermined set of rules, define at least one default support structure for the at least one body region in the at least one identified slice; and if the at least one body region in the at least one identified slice meets the predetermined set of rules, define at least one improved support structure for the at least one body region in the at least one identified slice.

In some embodiments, the at least one improved support structure is at least one of occupies less space on a fabrication tray of the 3D printing system and requires less supporting material than the at least one default support structure.

In some embodiments, in order to define the at least one improved support structure, the support structure definition module is configured to: select a subset of preceding slices of the multiple slices that precede the at least one identified slice, wherein each of the slices of the subset of preceding slices has to include at least one support region to be filled with a supporting material when printing the at least one 3D object, to thereby form the at least one support structure needed to support the at least one body region in the at least one identified slice; and define at least one support region for each slice of the subset of preceding slices such that a width of the at least one support region in the subset of preceding slices gradually increases between a last slice in the subset that is adjacent to the at least one identified slice and a first slice in the subset.

In some embodiments, in order to determine that the at least one body region in the at least one identified slice meets the predetermined set of rules, the support structure definition module is configured to: determine that a width of the at least one body region in the at least one identified slice is smaller than a specified width threshold.

In some embodiments, in order to determine that the at least one body region in the at least one identified slice meets the predetermined set of rules, the support structure definition module is configured to: determine that a distance between the at least one body region in the at least one identified slice and at least one body region in one of preceding slices immediately below the at least one body region in the at least one identified slice or the fabrication tray is larger than a specified distance threshold.

In some embodiments, in order to determine that the at least one body region in the at least one identified slice meets the predetermined set of rules, the support structure definition module is configured to: determine that a length of the at least one body region in the at least one identified slice is larger than a specified length threshold.

In some embodiments, in order to determine that the at least one body region in the at least one identified slice meets the predetermined set of rules, the support structure definition module is configured to: determine that there are no body regions in at least one of slices that are subsequent to the at least one identified slice that are wider than the at least one body region in the at least one identified slice.

In some embodiments, the slicing module is configured to: determine whether the at least one improved support structure defined for the at least one 3D object obstructs the construction of at least one other 3D object on the fabrication tray; and if so, modify a location of one or more of the at least one 3D object and the at least one another 3D object on the fabrication tray to avoid the obstruction thereof.

These, additional, and/or other aspects and/or advantages of the present invention are set forth in the detailed description which follows, possibly inferable from the detailed description, and/or learnable by practice of the present invention.

### BRIEF DESCRIPTION OF THE DRAWINGS

For a better understanding of embodiments of the invention and to show how the same can be carried into effect, reference will now be made, purely by way of example, to the accompanying drawings in which like numerals designate corresponding elements or sections throughout.

In the accompanying drawings:

FIG. 1 is a schematic illustration of a 3D printing system for printing 3D objects, according to some embodiments of the invention;

FIGS. 2A-2D are schematic illustrations of various options of printing a 3D object using a 3D printing system;

FIG. 3 is a schematic block diagram of a system for defining at least one support structure for at least one 3D object to be printed using a 3D printing system, according to some embodiments of the invention;

FIGS. 4A and 4B show different examples of defining at least one support structure for at least one 3D object to be printed using a 3D printing system, according to some embodiments of the invention; and

FIG. 5 is a flowchart of a method of defining at least one support structure for at least one 3D object to be printed using a 3D printing system, according to some embodiments of the invention.

It will be appreciated that, for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention are described. For purposes of explanation, specific configurations and details are set forth in order to provide a thorough understanding of the present invention. However, it will also be apparent to one skilled in the art that the present invention can be practiced without the specific details presented herein. Furthermore, well known features can have been omitted or simplified in order not to obscure the present invention. With specific reference to the drawings, it is stressed that the particulars shown are by way of example and for purposes of illustrative discussion of the present invention only and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention can be embodied in practice.

Before at least one embodiment of the invention is explained in detail, it is to be understood that the invention is not limited in its application to the details of structure and the arrangement of the components set forth in the following description or illustrated in the drawings. The invention is applicable to other embodiments that can be practiced or carried out in various ways as well as to combinations of the disclosed embodiments. Also, it is to be understood that the phraseology and terminology employed herein is for the purpose of description and should not be regarded as limiting.

Unless specifically stated otherwise, as apparent from the following discussions, it is appreciated that throughout the specification discussions utilizing terms such as “processing”, “computing”, “calculating”, “determining”, “enhancing” or the like, refer to the action and/or processes of a computer or computing system, or similar electronic computing device, that manipulates and/or transforms data represented as physical, such as electronic, quantities within the computing system's registers and/or memories into other data similarly represented as physical quantities within the computing system's memories, registers or other such information storage, transmission or display devices. Any of the disclosed modules or units can be at least partially implemented by a computer processor.

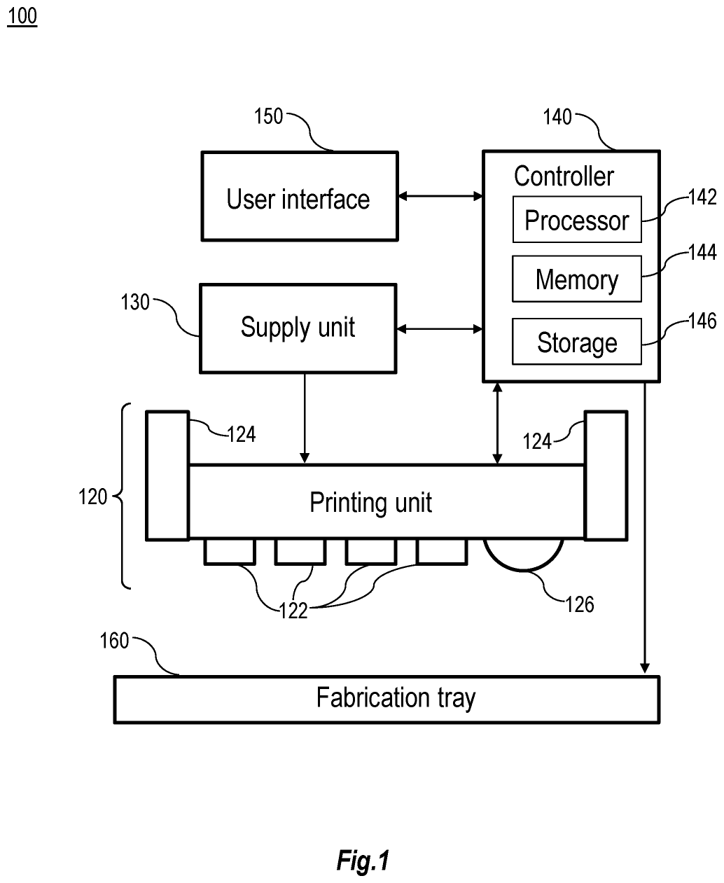

Reference is now made to FIG. 1, which is a schematic illustration of a 3D printing system 100 for printing 3D objects, according to some embodiments of the invention.

According to some embodiments, 3D printing system 100 may include a printing unit 120, a supply unit 130, a controller 140, a user interface 150 and a fabrication tray 160. Controller 140 may be configured to control all elements of 3D printing system 100.

According to some embodiments, printing unit 120 may include one or more print heads 122, one or more hardening subunits 124, and one or more leveling subunits 126. Print heads 122 may be adapted to deposit material using any ink-jet method. Printing unit 120 may move horizontally in both X and Y directions and optionally also vertically in the Z direction, above a square or rectangular fabrication tray 160. In some other embodiments, printing unit 120 is moving radially above a circular fabrication tray 160. In some further embodiments, some or all of the elements constituting printing unit 160 (e.g., leveling subunit 126, hardening unit 124, print heads 122) are mounted at distinct locations of printing system 100 and can be either static or mobile. In some embodiments, the fabrication tray is static and in some other embodiments the fabrication tray is mobile, e.g. a rotary fabrication tray, or moving in the X, Y and/or Z directions.

Each print head 122 may deposit one or more materials, such that two or more materials may be deposited in a single deposition scan. Print head(s) 122 may be fed with the material(s) supplied by supply unit 130. As known in the art, the term “print head” or “3D printing head” refers to a hardware component that is suitable to dispense 3D printing material(s) at a predefined position Implementations of commercially available 3D printing heads may include a single channel (e.g., hold a single type or color of printing material) or a multiple channel (e.g., hold one or more types or colors of printing materials). In some embodiments, single print head of print heads 122 may be configured to deposit different materials (e.g., dual channel print head, multiple channel print head).

Hardening subunit(s) 124 may include any device that is adapted to emit light, heat and the like that may cause the printed material to harden. For example, hardening subunit(s) 124 may include one or more ultraviolet (UV) lamps (e.g., mercury lamp, UV LED assembly) for curing the deposited material.

Leveling subunit 126 may include any device that may be configured to level and/or control the thickness and/or flatness of the newly formed layer by sweeping over the layer and removing excess material. For example, leveling subunit 126 may be a roller. Leveling subunit 126 may include a waste collection device (not shown) for collecting the excess material generated during the leveling process.

Supply unit 130 may include one or more material containers or cartridges for supplying the material(s) to print head(s) 122.

Controller 140 may include a processor 142, a memory 144 and a storage 146. Processor 142 may, for example, control the movement of printing unit 120 in a desired direction. Memory 144 may, for example, include an executable code. The executable code may include codes or instructions for controlling 3D printing system 100 to print 3D objects according to embodiments of the present invention. Storage 146 may store files that include design parameters of the 3D objects and the corresponding support structures to be printed by 3D printing system 100.

User interface 150 may be or may include input devices such as a mouse, a keyboard, a touch screen or pad or any suitable input devices and output devices. User interface 50 may allow a user to upload or update codes and instructions for controlling printing of 3D objects according to some embodiments of the invention and/or to upload and update files comprising the design of the 3D objects (e.g., computer aided design (CAD) files) into storage 146.

Fabrication tray 160 may be any tray, building or printing surface that is suitable to bear 3D objects and their corresponding support constructions as they are being printed, e.g., fabricated. Fabrication tray 160 may be attached, connected to or include an X-Y table and may be controlled, e.g., by controller 140, to move in the Z direction and/or optionally in the X-Y plane according to the requirements of the printing process. In some other embodiments, fabrication tray 160 is a circular tray configured to rotate around a central axis and to optionally move in the Z direction.

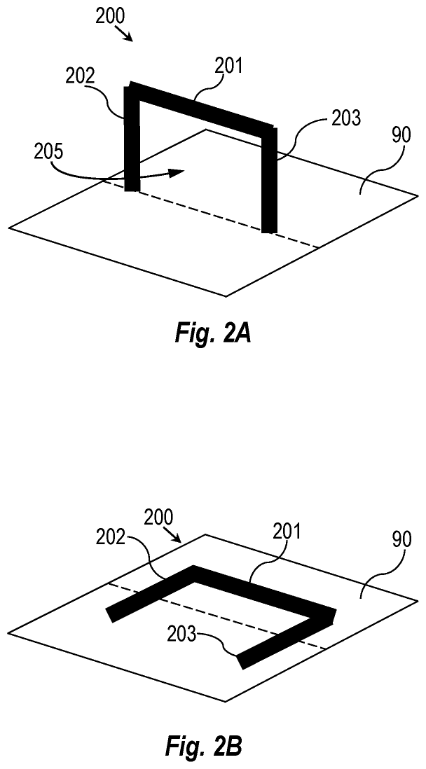

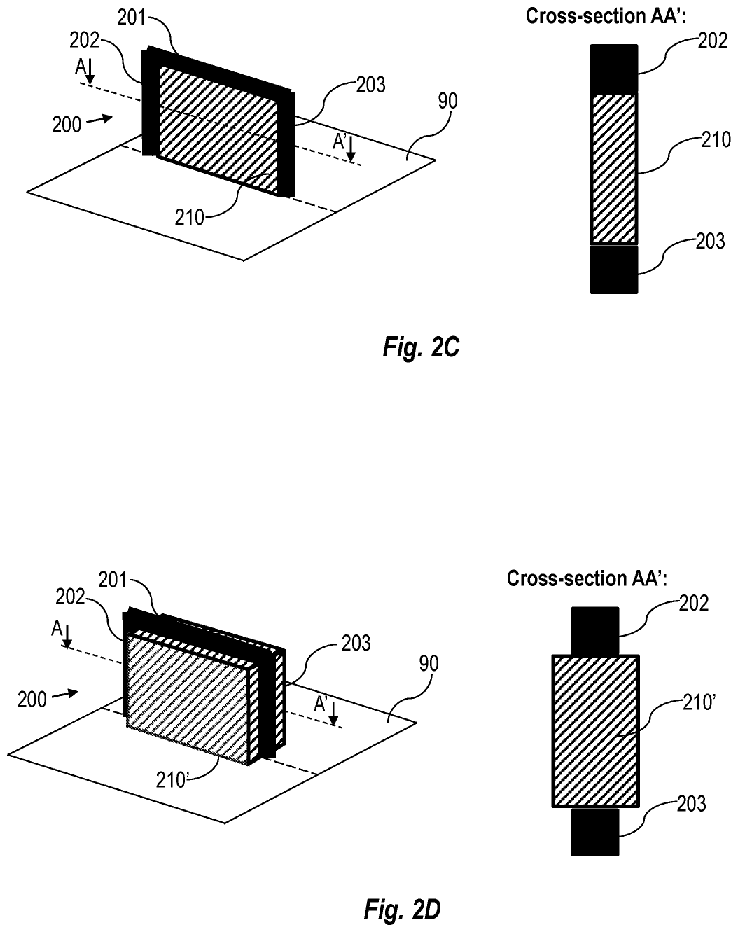

Reference is now made to FIGS. 2A, 2B, 2C and 2D, which are schematic illustrations of various options of printing a 3D object 200 using a 3D printing system.

FIG. 2A depicts a 3D object 200 including a crossbar 201 supported at each end by bars 202, 203, respectively, as an example of a 3D object printable by a 3D printing system (such as system 100 described above with respect to FIG. 1). 3D object 200 may include a gap 205 surrounded by crossbar 201 and bars 202, 203.

Typically, 3D printing systems (such as 3D printing system 100) print 3D objects (such as 3D object 200) by depositing a building material and/or a support material, in layers, to form the 3D object and/or a support structure, respectively.

For example, 3D object 200 may be placed in its vertical position (as shown in FIG. 2A) or in its horizontal position, e.g., when laying on its side (as shown in FIG. 2B) on a fabrication tray 90 of the 3D printing system (e.g., such as fabrication tray 160 described above with respect to FIG. 1). In the example shown in FIG. 2B, none or no substantial amount of support material is required to print 3D object 200. However, 3D object 200 may occupy significantly more space on fabrication tray 90 when printed in a horizontal position as compared to being printed in a vertical position as shown in FIG. 2A. This may be a disadvantage, especially when printing more than one 3D object during a single print cycle.

FIGS. 2C and 2D show 3D object 200 being printed in a vertical position on fabrication tray 90. In order to print such a 3D object 200 in a vertical position, the 3D printing system deposits layer-by-layer a building material and a support material to form the 3D object 200 and a support structure 210 or 210′, as shown in FIGS. 2C and 2D respectively. The support structure is constructed to fill portions of the 3D object that are designed to be an empty space (such as gap 205 in 3D object 200) in order to support portions of the 3D object to be printed subsequently, e.g., above the empty space (such as crossbar 201 in 3D object 200).

Typically, 3D printing systems print 3D objects based on 3D cross-sectional digital data including a set of horizontal slices each representing a respective horizontal cross-section of the 3D object. Each of the horizontal slices is typically generated on a standalone basis and directly uploaded to the printing systems for printing. The data from the slice may then be purged from a memory of the 3D printing system when the printing of the slice is completed. Thus, at a specific time t, the 3D printing system has generally only a partial information regarding the geometry of the whole 3D object.

Accordingly, 3D printing systems are typically configured to identify regions in at least some of the slices that are designed to be an empty space and deposit the support material into the regions thereof and thereby construct the support structure. In FIG. 2C, dashed line AA′ indicates a cross-section of the vertical 3D object to be built, by depositing at least a modeling material to form bars 202 and 203, as well as at least a support material to form support construction 210 occupying gap 205 (shown in FIG. 2A) between bars 202, 203. In such a manner, support structure 210 may be constructed to support the formation of crossbar 201, by occupying the gap 205 immediately below crossbar 201 while it is being printed, e.g., within a region defined by a top projection of crossbar 201, and then support structure 210 may be removed to reveal gap 205.

However, support material typically has inferior mechanical properties as compared to the building material(s) used to construct the 3D object. Thus, the support structure constructed immediately below the portion of the 3D object to be supported and within the region defined by the top projection thereof, like support structure 210 shown in FIG. 2C, may not be strong enough to support the portion, and as a result, may fail and cause termination of the printing.

Accordingly, 3D printing systems may, in some cases, construct a support structure 210′ that extends beyond the dimensions defined by the projection of the top, e.g., crossbar 201 portion, as shown for example in FIG. 2D. For example, support structure 210′ may be wider (as shown for example in the cross-section (slice) AA′ of FIG. 2A) and have stronger mechanical properties as compared to support structure 210. However, support structure 210′ may include more support material and take up more space on the fabrication tray than support structure 210, thus wasting material and space on fabrication tray 90.

There is, therefore, a need for a system and method capable of predefining an improved support structure(s) for 3D object(s) for printing thereof using a 3D printing system. The improved support structures may be strong enough to support portions of the 3D object being printed and yet occupy less space and/or require less support material(s) than typical/default support structures (such as support structures 210, 210′ as described above with respect to FIGS. 2C and 2D, respectively).

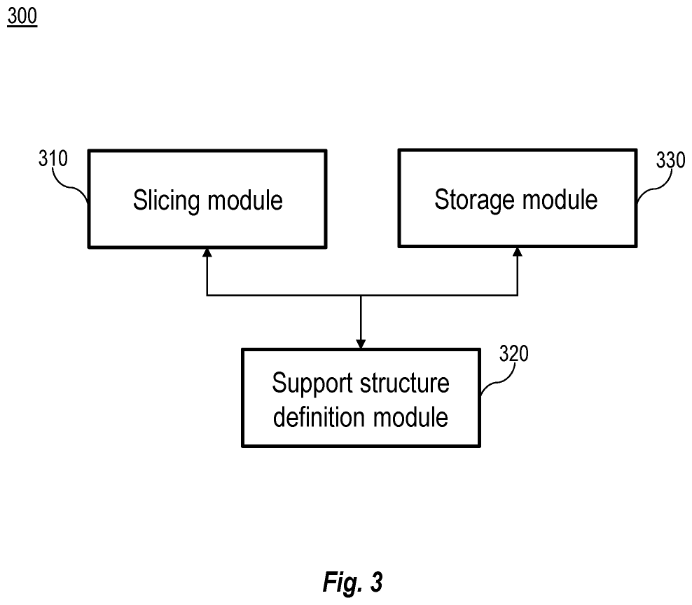

Reference is now made to FIG. 3, which is a schematic block diagram of a system 300 for defining at least one support structure for at least one 3D object to be printed using a 3D printing system, according to some embodiments of the invention.

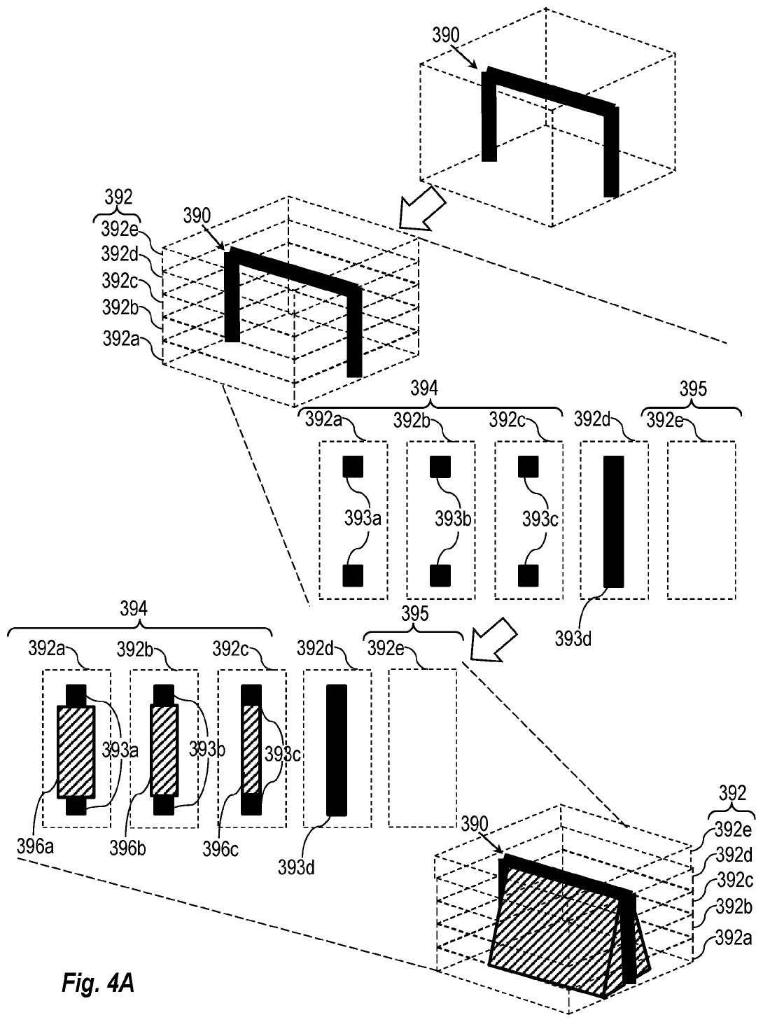

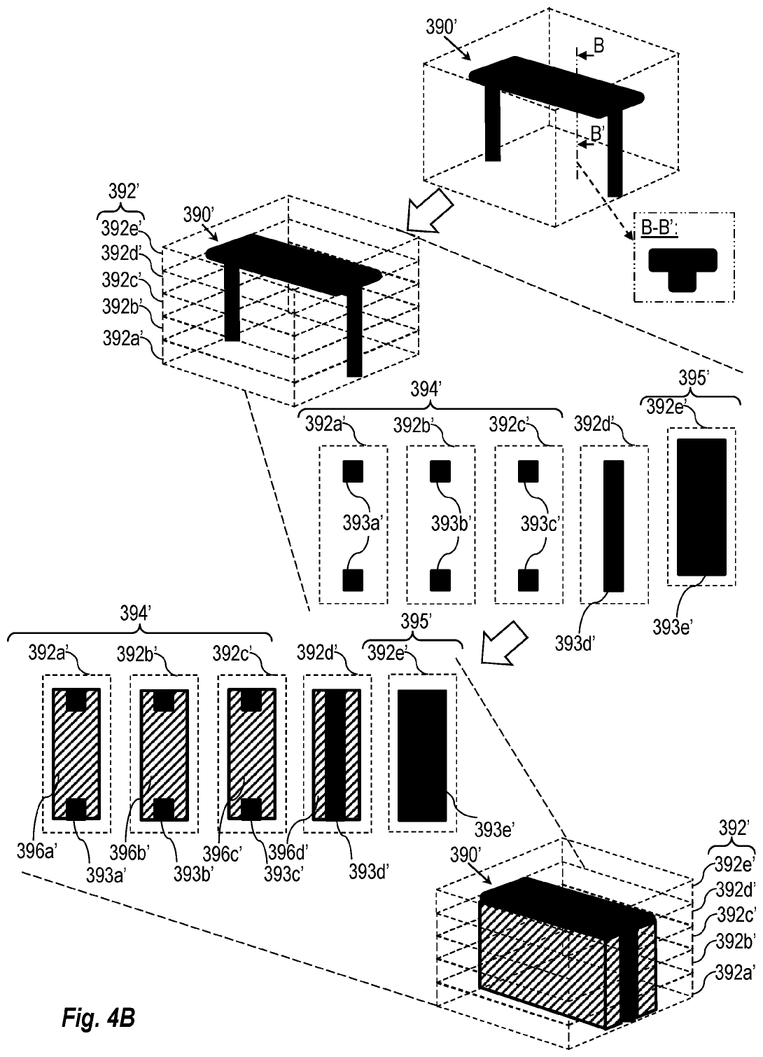

Reference is also made to FIGS. 4A and 4B, which show different examples of predefining at least one support structure for at least one 3D object to be printed using a 3D printing system, according to some embodiments of the invention.

According to some embodiments, system 300 may include a slicing module 310, a support structure definition module 320 and a storage module 330. Slicing module 310, support structure definition module 320 and storage module 330 may be in communication with each other (e.g., as shown in FIG. 3).

According to some embodiments, slicing module 310 may be configured to receive a 3D digital model of one or more 3D objects or an assembly of 3D object(s) or object parts to be printed using a 3D printing system. The 3D digital model may be provided as one or more files in, for example, STL, 3MF, OBJ or VRML format. The 3D printing system may be similar to, for example, 3D printing system 100 described above with respect to FIG. 1.

Slicing module 310 may be configured to slice the 3D digital model to generate multiple slices, wherein each of at least some of the multiple slices includes at least one body region that represents a respective horizontal cross-section of the 3D object(s).

For example, FIG. 4A shows a 3D digital model 390 of a 3D object (such as 3D object 200 described above with respect to FIG. 2A). 3D digital model 390 may be sliced into multiple slices 392 (e.g., a first slice 392a, a second slice 392b, a third slice 392c, a fourth slice 392d and a fifth slice 392e) as shown in FIG. 4A. Some of slices 392 may have at least one body region 393 that represents a respective horizontal cross-section of the at least one 3D object. For example, first slice 392a may include body regions 393a, second slice 392b may include body regions 393b, third slice 392c may include body regions 393c, and/or fourth slice 392d may include a body region 393d. Fifth slice 392e may, for example, not include body region(s) and support region(s) but only “no-print” regions, which are regions where printing materials are not deposited (e.g., as shown in FIG. 4A).

In some embodiments, slicing module 310 may be configured to deliver the generated multiple slices to storage module 330 which may be configured to store the multiple slices.

According to some embodiments, support structure definition module 320 may be configured to predefine one or more support structures for the 3D object(s), prior to actual printing of the 3D object(s) using the 3D printing system.

Support structure definition module 320 may be configured to analyze at least some of the multiple slices. Support structure definition module 320 may be configured to identify, based on the analysis thereof, at least one slice of the multiple slices that includes at least one body region (or at least a portion thereof) that has to be supported by at least one support structure when printing the at least one 3D object.

For example, fourth slice 392d includes body region 393d, at least a portion of which has to be supported by one or more support structures when printing the 3D object(s) (e.g., as shown in FIG. 3B).

In some embodiments, support structure definition module 320 may be configured to select a subset of preceding slices of the multiple slices that precede the at least one identified slice, wherein each of the slices of the subset of preceding slices has to include at least one support region, to thereby form the support structure(s) needed to support the at least one body region (or the portion thereof) in the at least one identified slice.

For example, a subset 394 of preceding slices may include first slice 392a, second slice 392b and third slice 392c that have to include at least one support region to form the support structure(s) under body region 393d identified in fourth slice 392d.

In some embodiments, support structure definition module 320 may be configured to select a subset of subsequent slices of the multiple slices that are subsequent to the at least one identified slice.

For example, a subset 395 of subsequent slices may include fifth slice 392e that is subsequent to identified fourth slice 392d (e.g., as shown in FIG. 4A).

In some embodiments, support structure definition module 320 may be configured to determine, based on a predetermined set of rules, whether an improved support structure may be defined at least for the body region(s) in the at least one identified slice.

The predetermined set of rules may, for example, include at least one of: a specified width threshold, a specified distance threshold (e.g., height from an underlying body region/tray), a specified length threshold and/or an absence of body region(s) in one of the subsequent slices that is wider than the body region(s) in the at least one identified slice.

For example, support structure definition module 320 may be configured to determine whether the body region(s) in the at least one identified slice meet the predetermined set of rules.

In this example, support structure definition module 320 may be configured to determine whether a width of the body region(s) in the at least one identified slice is smaller than the specified width threshold.

Yet, in this example, support structure definition module 320 may be configured to determine whether a distance between (i) the body region(s) in the at least one identified slice and (ii) body region(s) in one of the preceding slices immediately below the body region(s) in the at least one identified slice or (iii) a fabrication tray, is larger than the specified distance threshold.

Yet, in this example, support structure definition module 320 may be configured to determine whether a length of the body region(s) in the at least one identified slice is larger than the specified length threshold.

Yet, in this example, support structure definition module 320 may be configured to determine whether there are no body regions in the subsequent slices that are wider than the body region(s) in the identified slice.

In some embodiments, when the body region(s) in the at least one identified slice meet the predetermined set of rules (e.g., as described above), support structure definition module 320 may be configured to define one or more improved support structures for the body region(s) in the at least one identified slice.

In these embodiments, support structure definition module 320 may be configured to define, for each of the subset of preceding slices, at least one support region such that a width of the at least one support region in the subset of preceding slices may gradually increase between a last slice in the subset that is adjacent to the at least one identified slice and a first slice in the subset. In this manner, the improved support structure may, for example, have a triangular prism shape (e.g., as shown in FIG. 4A).

For example, a first support region 396a may be defined for first slice 392a, a second support region 396b may be defined for second slice 392b, and a third support region 396c may be defined for third slice 392c (e.g., as shown in FIG. 3B). Third support region 396c in third slice 392c (e.g., the last slice in subset 394) may, for example, have the same width as a portion of body region 393d in fourth slice 392d that needs to be supported. Third support region 396c in third slice 392c (e.g., the last slice in subset 394) may be narrower than, for example, second support region 396b in second slice 392b that may be narrower than, for example, first support region 396a in first slice 392a (e.g., the first slice of subset 394), e.g., as shown in FIG. 4A.

In other embodiments, when the body region(s) in the at least one identified slice do not meet the predetermined set of rules, support structure definition module 320 may be configured to define a default support structure (e.g., such as support structure 210 described above with respect to FIG. 2C).

For example, if the width of the body region(s) in the at least one identified slice is larger than the specified width threshold, the default support structure (such as support structure 210 described above with respect to FIG. 2C) may be strong enough, and thus no improved support structure is required.

In another example, one of the slices that are subsequent to the at least one identified slice may include one or more body region(s) that is wider than the body region(s) in the at least one identified slice. In this case, the support structure for the wider body region in the subsequent slice may apparently include the support for the body region(s) of the at least one identified slice and thus no improved support structure is required.

For example, FIG. 4B shows a 3D digital model 390′ of 3D object in which its fifth slice 392e′ includes body region 393e′ that is wider than body region 393d′ in its fourth slice 392d′. In this case, support regions 396a′, 396b′, 396c′, 396d′ of slices 392a′, 392b′, 392c′, 392d′, respectively, may have substantially the same width as body region 393e′ of fifth slice 392e′ and thus may apparently include support regions 396a, 396b, 396c (e.g., improved support regions) described above with respect to FIG. 4A. Thus, no improved support structure is required.

In some embodiments, support structure definition module 320 may be configured to determine that the support region(s) defined for a particular 3D object do not inhibit the construction of other 3D objects (e.g., adjacent objects) on the fabrication tray. In the case of a detected inhibition, support structure definition module 320 may be configured to modify the location of the 3D objects on the fabrication tray based on the multiple slices to avoid the inhibition of their construction.

According to some embodiments, slicing module 310 may be configured to slice the 3D digital model to thereby generate a 3D digital dataset including the multiple slices and having a 3D digital dataset resolution that is coarser than a predetermined resolution of the 3D printing system.

The 3D digital dataset may be then used for predefining the support structure(s) for the 3D model (e.g., as described above with respect to FIGS. 3, 4A and 4B). It has been found that defining the supporting structure(s) using the 3D digital dataset resolution that is smaller than the printing resolution of the 3D printing system enables getting a faster definition of the support structure(s).

In various embodiments, the 3D digital dataset resolution used for generating the 3D digital dataset with slicing module 310 may be selected based on a number and/or a complexity of the 3D object(s) and a desired time (e.g., defined by a user) required for support structure(s) to be defined.

According to various embodiments, each of slicing module 310, support structure definition module 320 and/or storage module 330 may be implemented on its own computing device, a single (e.g., shared) computing device, or a combination of computing devices. In various embodiments, the communication between slicing module 310, support structure definition module 320 and/or storage module 330 may be wired or wireless.

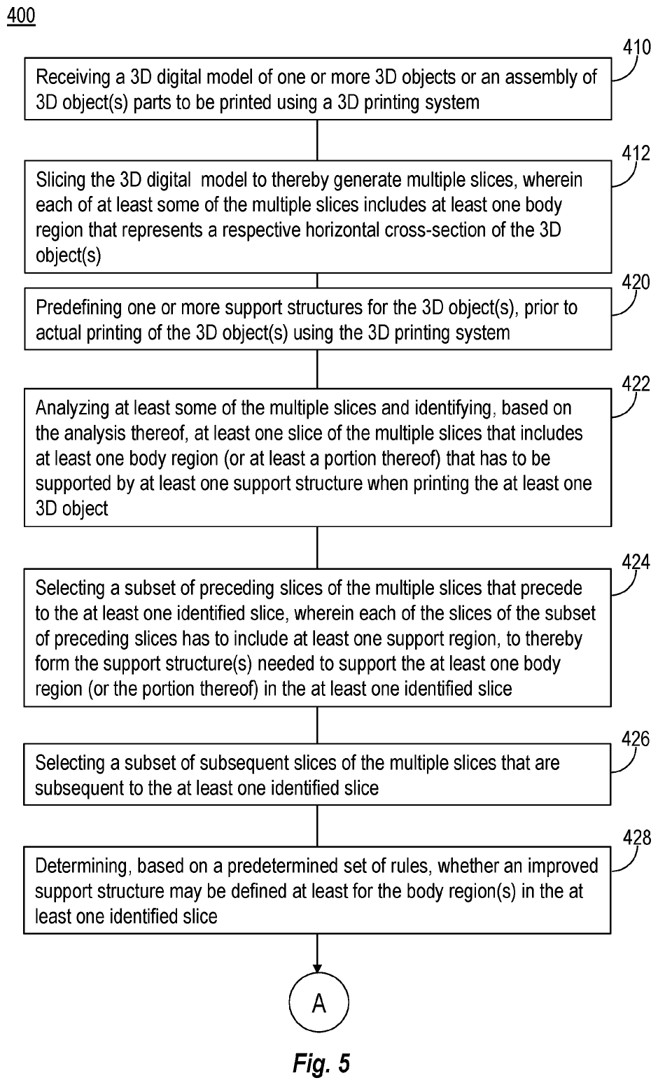

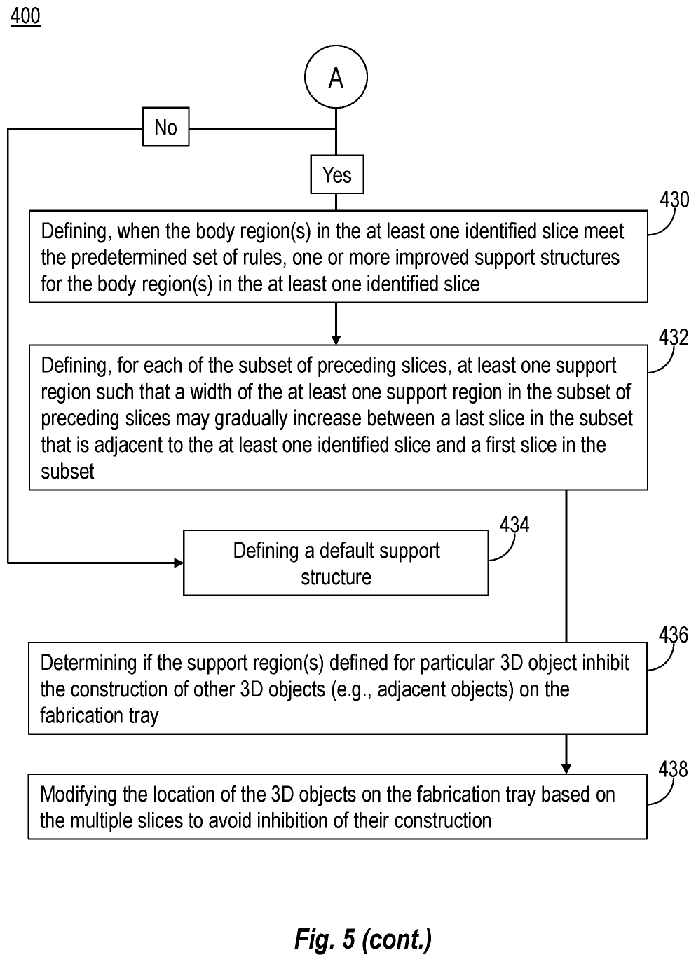

Reference is made to FIG. 5, which is a flowchart of a method 400 of predefining at least one support structure for at least one 3D object to be printed using a 3D printing system, according to some embodiments of the invention.

Method 400 may be implemented by a system for predefining at least one support structure for at least one 3D object for printing thereof using a 3D printing system (such as system 300 described above with respect to FIGS. 3, 4A and 4B), which may be configured to implement method 400.

According to some embodiments, method 400 may include receiving a 3D digital model of one or more 3D objects or an assembly of 3D object(s) parts to be printed using a 3D printing system (stage 410). For example, the 3D model may be similar to 3D model 390 described above with respect to FIG. 4A.

In some embodiments, method 400 may include slicing the 3D digital model to thereby generate multiple slices, wherein each of at least some of the multiple slices includes at least one body region that represents a respective horizontal cross-section of the 3D object(s) (stage 412). For example, the slicing of the 3D digital model into the multiple slices may be performed by slicing module 310 of system 300 as describe above with respect to FIGS. 3, 4A and 4B.

According to some embodiments, method 400 may include predefining one or more support structures for the 3D object(s), prior to actual printing of the 3D object(s) using the 3D printing system (stage 420). For example, the predefining one or support structures may be performed by support structure definition module 320 of system 300 as described above with respect to FIGS. 3, 4A and 4B.

In some embodiments, method 400 may include analyzing at least some of the multiple slices and identifying, based on the analysis thereof, at least one slice of the multiple slices that includes at least one body region (or at least a portion thereof) that has to be supported by at least one support structure when printing the at least one 3D object (stage 422) (e.g., as described above with respect to FIGS. 3, 4A and 4B).

In some embodiments, method 400 may include selecting a subset of preceding slices of the multiple slices that precede the at least one identified slice, wherein each of the slices of the subset of preceding slices has to include at least one support region, to thereby form the support structure(s) needed to support the at least one body region (or the portion thereof) in the at least one identified slice (stage 424) (e.g., as described above with respect to FIGS. 3, 4A and 4B).

In some embodiments, method 400 may include selecting a subset of subsequent slices of the multiple slices that are subsequent to the at least one identified slice (stage 426) (e.g., as described above with respect to FIGS. 3, 4A and 4B).

In some embodiments, method 400 may include determining, based on a predetermined set of rules, whether an improved support structure may be defined at least for the body region(s) in the at least one identified slice (stage 428) (e.g., as described above with respect to FIGS. 3, 4A and 4B).

The predetermined set of rules may, for example, include at least one of: a specified width threshold, a specified distance threshold, a specified length threshold and/or an absence of building region(s) in one of the subsequent slices that is wider than the body region(s) in the at least one identified slice (e.g., as described above with respect to FIGS. 3, 4A and 4B).

In some embodiments, method 400 may include determining that a width of the at least one body region in the at least one identified slice is smaller than a specified width threshold to thereby determine that the at least one body region in the at least one identified slice meets the predetermined set of rules.

In some embodiments, method 400 may include determining that a distance between the at least one body region in the at least one identified slice and at least one body region in one of preceding slices immediately below the at least one body region in the at least one identified slice or a fabrication tray, is larger than a specified distance threshold to thereby determine that the at least one body region in the at least one identified slice meets the predetermined set of rules.

In some embodiments, method 400 may include determining that a length of the at least one body region in the at least one identified slice is larger than the specified length threshold to thereby determine that the at least one body region in the at least one identified slice meets the predetermined set of rules.

In some embodiments, method 400 may include determining that there are no body regions in at least one of slices that are subsequent to the at least one identified slice that are wider than the at least one body region in the at least one identified slice to thereby determine that the at least body region in the at least one identified slice meets the set of predetermined rules.

In some embodiments, method 400 may include defining, when the body region(s) in the at least one identified slice meet the predetermined set of rules, one or more improved support structures for the body region(s) in the at least one identified slice (stage 430).

In these embodiments, method 400 may include defining, for each of the subset of preceding slices, at least one support region such that a width of the at least one support region in the subset of preceding slices may gradually increases between a last slice in the subset that is adjacent to the at least one identified slice and a first slice in the subset (stage 432) (e.g., as described above with respect to FIGS. 3, 4A and 4B).

In some other embodiments, when the body region(s) in the at least one identified slice do not meet the predetermined set of rules, method 400 may include defining a default support structure (stage 434) (e.g., as described above with respect to FIGS. 3, 4A and 4B).

In some embodiments, method 400 may include determining if the support region(s) defined for a particular 3D object inhibit the construction of other 3D objects (e.g., adjacent objects) on the fabrication tray (stage 436) (e.g., as described above with respect to FIGS. 3, 4A and 4B).

In some embodiments, method 400 may include modifying the location of the 3D objects on the fabrication tray based on the multiple slices to avoid inhibition of their construction (stage 438) (e.g., as described above with respect to FIGS. 3, 4A and 4B).

Advantageously, the disclosed system and method may enable to predefine an improved support structure(s) for 3D object(s) for printing thereof using a 3D printing system. The improved support structures may be strong enough to support portions of the 3D object being printed and yet occupy less space and/or require less support material than typical/default support structures, thus overcoming the disadvantages of the typical/default support structures currently used in 3D printing (e.g., as described above with respect to FIGS. 3, 4A, 4B and 5).

Aspects of the present invention are described above with reference to flowchart illustrations and/or portion diagrams of methods, apparatus (systems) and computer program products according to embodiments of the invention. It will be understood that each portion of the flowchart illustrations and/or portion diagrams, and combinations of portions in the flowchart illustrations and/or portion diagrams, can be implemented by computer program instructions. These computer program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or portion diagram or portions thereof.

These computer program instructions can also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or portion diagram portion or portions thereof. The computer program instructions can also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or portion diagram portion or portions thereof.

The aforementioned flowchart and diagrams illustrate the architecture, functionality, and operation of possible implementations of systems, methods and computer program products according to various embodiments of the present invention. In this regard, each portion in the flowchart or portion diagrams can represent a module, segment, or portion of code, which includes one or more executable instructions for implementing the specified logical function(s). It should also be noted that, in some alternative implementations, the functions noted in the portion can occur out of the order noted in the figures. For example, two portions shown in succession can, in fact, be executed substantially concurrently, or the portions can sometimes be executed in the reverse order, depending upon the functionality involved. It will also be noted that each portion of the portion diagrams and/or flowchart illustration, and combinations of portions in the portion diagrams and/or flowchart illustration, can be implemented by special purpose hardware-based systems that perform the specified functions or acts, or combinations of special purpose hardware and computer instructions.

In the above description, an embodiment is an example or implementation of the invention. The various appearances of “one embodiment”, “an embodiment”, “certain embodiments” or “some embodiments” do not necessarily all refer to the same embodiments. Although various features of the invention can be described in the context of a single embodiment, the features can also be provided separately or in any suitable combination. Conversely, although the invention can be described herein in the context of separate embodiments for clarity, the invention can also be implemented in a single embodiment. Certain embodiments of the invention can include features from different embodiments disclosed above, and certain embodiments can incorporate elements from other embodiments disclosed above. The disclosure of elements of the invention in the context of a specific embodiment is not to be taken as limiting their use in the specific embodiment alone. Furthermore, it is to be understood that the invention can be carried out or practiced in various ways and that the invention can be implemented in certain embodiments other than the ones outlined in the description above.

The invention is not limited to those diagrams or to the corresponding descriptions. For example, flow need not move through each illustrated box or state, or in exactly the same order as illustrated and described. Meanings of technical and scientific terms used herein are to be commonly understood as by one of ordinary skill in the art to which the invention belongs, unless otherwise defined. While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

1. A method of defining at least one support structure for at least one 3D object to be printed using a 3D printing system, the method comprising:
receiving a 3D digital model of at least one 3D object to be printed;
slicing the 3D digital model to generate multiple slices, wherein each of at least some of the multiple slices includes at least one body region that represents a respective horizontal cross-section of the at least one 3D object;
identifying at least one slice of the multiple slices that includes at least one body region that has to be supported by at least one support structure when printing the at least one 3D object;
determining whether the at least one body region in the at least one identified slice meets a predetermined set of rules;
if the at least one body region in the at least one identified slice does not meet the predetermined set of rules, defining at least one default support structure for the at least one body region in the at least one identified slice; and
if the at least one body region in the at least one identified slice meets the predetermined set of rules, defining at least one improved support structure for the at least one body region in the at least one identified slice.

2. The method of claim 1, wherein the at least one improved support structure is at least one of occupies less space on a fabrication tray of the 3D printing system and requires less supporting material than the at least one default support structure.

3. The method claim 1, wherein defining the at least one improved support structure comprises:
selecting a subset of preceding slices of the multiple slices that precede the at least one identified slice, wherein each of the slices of the subset of preceding slices has to include at least one support region to be filled with a supporting material when printing the at least one 3D object, to thereby form the at least one support structure needed to support the at least one body region in the at least one identified slice; and
defining at least one support region for each slice of the subset of preceding slices such that a width of the at least one support region in the subset of preceding slices gradually increases between a last slice in the subset that is adjacent to the at least one identified slice and a first slice in the subset.

4. The method of claim 1, wherein determining that the at least one body region in the at least one identified slice meets the predetermined set of rules comprises:
determining that a width of the at least one body region in the at least one identified slice is smaller than a specified width threshold.

5. The method of claim 1, wherein determining that the at least one body region in the at least one identified slice meets the predetermined set of rules comprises:
determining that a distance between the at least one body region in the at least one identified slice and at least one body region in one of preceding slices immediately below the at least one body region in the at least one identified slice or the fabrication tray is larger than a specified distance threshold.

6. The method of claim 1, wherein determining that the at least one body region in the at least one identified slice meets the predetermined set of rules comprises:
determining that a length of the at least one body region in the at least one identified slice is larger than a specified length threshold.

7. The method of claim 1, wherein determining that the at least one body region in the at least one identified slice meets the predetermined set of rules comprises:
determining that there are no body regions in at least one slices that are subsequent to the at least one identified slice that is wider than the at least one body region in the at least one identified slice.

8. The method of claim 1, comprising:
determining if the at least one improved support structure defined for the at least one 3D object obstruct the construction of at least one other 3D object on the fabrication tray; and
if so, modifying a location of one or more of the at least one 3D object and the at least one another 3D object on the fabrication tray to avoid the obstruction thereof.

9. A system for defining at least one support structure for at least one 3D object to be printed using a 3D printing system, the system comprising:
a slicing module configured to:
receive a 3D digital model of at least one 3D object to be printed; and
slice the 3D digital model to generate multiple slices, wherein each of at least some of the multiple slices includes at least one body region that represents a respective horizontal cross-section of the at least one 3D object; and
a support structure definition module configured to:
identify at least one slice of the multiple slices that includes at least one body region that has to be supported by at least one support structure when printing the at least one 3D object;
determine whether the at least one body region in the at least one identified slice meets a predetermined set of rules;
if the at least one body region in the at least one identified slice does not meet a predetermined set of rules, define at least one default support structure for the at least one body region in the at least one identified slice; and
if the at least one body region in the at least one identified slice meets the predetermined set of rules, define at least one improved support structure for the at least one body region in the at least one identified slice.

10. The system of claim 9, wherein the at least one improved support structure is at least one of occupies less space on a fabrication tray of the 3D printing system and requires less supporting material than the at least one default support structure.

11. The system of claim 9, wherein in order to define the at least one improved support structure, the support structure definition module is configured to:
select a subset of preceding slices of the multiple slices that precede the at least one identified slice, wherein each of the slices of the subset of preceding slices has to include at least one support region to be filled with a supporting material when printing the at least one 3D object, to thereby form the at least one support structure needed to support the at least one body region in the at least one identified slice; and
define at least one support region for each slice of the subset of preceding slices such that a width of the at least one support region in the subset of preceding slices gradually increases between a last slice in the subset that is adjacent to the at least one identified slice and a first slice in the subset.

12. The system of claim 9, wherein in order to determine that the at least one body region in the at least one identified slice meets the predetermined set of rules, the support structure definition module is configured to:
determine that a width of the at least one body region in the at least one identified slice is smaller than a specified width threshold.

13. The system of claim 9, wherein in order to determine that the at least one body region in the at least one identified slice meets the predetermined set of rules, the support structure definition module is configured to:
determine that a distance between the at least one body region in the at least one identified slice and at least one body region in one of preceding slices immediately below the at least one body region in the at least one identified slice or the fabrication tray is larger than a specified distance threshold.

14. The system of claim 9, wherein in order to determine that the at least one body region in the at least one identified slice meets the predetermined set of rules, the support structure definition module is configured to:
determine that a length of the at least one body region in the at least one identified slice is larger than a specified length threshold.

15. The system of claim 9, wherein in order to determine that the at least one body region in the at least one identified slice meets the predetermined set of rules, the support structure definition module is configured to:
determine that there are no body regions in at least one of slices that are subsequent to the at least one identified slice that are wider than the at least one body region in the at least one identified slice.

16. The system of claim 9, wherein the slicing module is configured to:
determine whether the at least one improved support structure defined for the at least one 3D object obstructs the construction of at least one other 3D object on the fabrication tray; and
if so, modify a location of one or more of the at least one 3D object and the at least one another 3D object on the fabrication tray to avoid the obstruction thereof.
